(19) United States
(12) Patent Application Publication
(10) Pub. No.: US 2009/0050904 A1
(43) Pub. Date: Feb. 26, 2009

(54) LIGHT EMITTING DIODE CIRCUIT

(76) Inventors: Meng-Han Hsieh, Hsinchu City (TW); Tay-Her Tsaur, Tai-Nan City (TW); Chi-Shun Weng, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/194,545

(22) Filed: Aug. 20, 2008

(30) Foreign Application Priority Data
Aug. 20, 2007 (TW) 096130716

(51) Int. Cl. H01L 33/00

(52) U.S. Cl. 257/79; 257/E33.001

(57) ABSTRACT

A light emitting diode circuit includes a chip and a light emitting diode. The chip includes a current control unit that is used for controlling a driving current flowing through a path. The light emitting diode is positioned outside of the chip and is coupled to the path. The light emitting diode generates a light source according to the driving current. The light emitting diode circuit can directly control the current value of a driving current flowing through the light emitting diode. In this way, the circuit design is simplified and the production cost of the electronic product is reduced.

### BACKGROUND OF THE INVENTION

1. Field of the Invention

The present invention relates to a light emitting diode circuit, and more particularly, to a light emitting diode circuit having a chip and a light emitting diode. The chip has a current control unit utilized for controlling a driving current flowing through a path.

2. Description of the Prior Art

Please refer to FIG. 1. FIG. 1 is a simplified diagram illustrating a pad connecting with a light emitting diode on a typical LED control chip 10. As shown in FIG. 1, the LED control chip 10 comprises a pad 110. The pad 110 is coupled to a light emitting diode 120 and a current-limiting resistor 20 that are outside of the chip 10. In general, the function of the current-limiting resistor 20 is to control the driving current flowing through the light emitting diode 120 so as to control the brightness of the light emitting diode 120. The current-limiting resistor 20 also prevents the driving current of the light emitting diode 120 from being too large, because the driving current affects the lifetime of the light emitting diode 120. The current-limiting resistor 20, however, is generally positioned on the print circuit board (PCB) outside of the LED control chip 10, and this greatly increases the hardware cost.

### SUMMARY OF THE INVENTION

It is therefore one of the objectives of the present invention to provide a light emitting diode circuit, in which the driving current flowing through the light emitting diode can be directly controlled by the control circuit inside the chip so as to decrease the hardware cost. It is therefore one of the objectives of the present invention to provide a light emitting diode circuit saving the extra current-limiting resistor.

According to an exemplary embodiment of the present invention, a light emitting diode circuit is disclosed. The light emitting diode circuit comprises a chip that comprises a current control unit used for controlling a driving current flowing through a path, and a light emitting diode that is positioned outside of the chip and coupled to the path. The light emitting diode generates a light source according to the driving current.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified diagram illustrating a pad connecting with a light emitting diode on a typical LED control chip.

FIG. 2 is a diagram illustrating a light emitting diode circuit according to a first exemplary embodiment of the present invention.

FIG. 3 is a diagram illustrating a light emitting diode circuit according to a second exemplary embodiment of the present invention.

FIG. 4 is a diagram illustrating a relation of a reference current to a driving current.

FIG. 5 is a diagram illustrating a light emitting diode circuit according to a third exemplary embodiment of the present invention.

FIG. 6 is a diagram illustrating a light emitting diode circuit according to a fourth exemplary embodiment of the present invention.

FIG. 7 is a diagram illustrating a light emitting diode circuit according to a fifth exemplary embodiment of the present invention

FIG. 8 is a diagram illustrating a light emitting diode circuit according to a sixth exemplary embodiment of the present invention

FIG. 9 is a diagram illustrating a light emitting diode circuit according to a seventh exemplary embodiment of the present invention

### DETAILED DESCRIPTION

Different features of the present invention are detailed as below in reference to the figures, and for convenience of explanation, the same elements in separate figures are indicated by the same reference numerals.

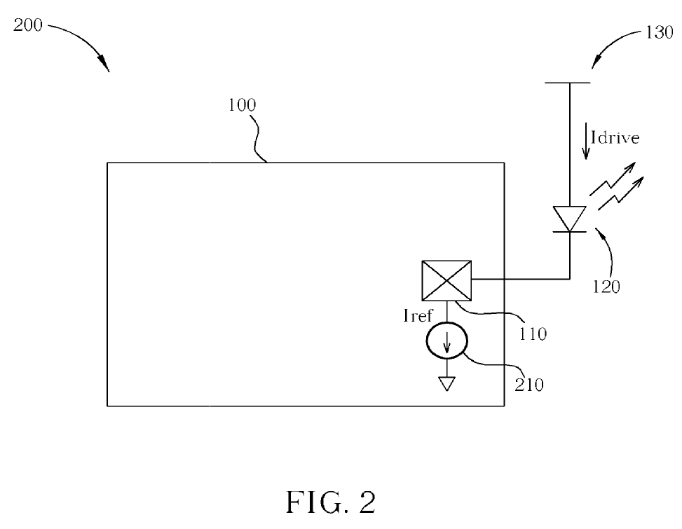

Please refer to FIG. 2. FIG. 2 is a diagram illustrating a light emitting diode circuit 200 according to a first exemplary embodiment of the present invention. As shown in FIG. 2, the light emitting diode circuit 200 comprises a chip 100, a light emitting diode 120 and a predetermined voltage source 130. The light emitting diode 120 and the predetermined voltage source 130 are both positioned outside of the chip 100. The chip 100 further comprises a current source 210 and a pad 110. The current source 210 is coupled to the light emitting diode 120 through the pad 110, and serves as a current control unit for providing a reference current Iref to generate a driving current Idrive on a path through the light emitting diode 120. The light emitting diode 120 is coupled between the predetermined voltage source 130 and the pad 110 (i.e., the path), and generates a light source according to the driving current Idrive. In this embodiment, the current source 210 is a constant current source. In addition, the current value of the driving current Idrive flowing through the light emitting diode 120 is equal to that of the reference current Iref; thus, the driving current Idrive can be controlled by simply controlling the reference current Iref. For example, the constant current source that provides the reference current Iref as 10 mA can be selected to be the current source 210, if the current value of the driving current Idrive is expected to be 10 mA. This ensures that the current value of the driving current Idrive flowing through the light emitting diode 120 is equal to 10 mA without any current-limiting resistor. Please note that, in this embodiment, the current source 210 is implemented by a constant current source; however, this is only for illustrative purposes and not a limitation of the present invention. For example, the current source 210 can be a variable current source for providing the reference current Iref according to a control voltage (gate voltage) to generate the driving current Idrive on the path through the light emitting diode 120. The light emitting diode 120 then generates a light source according to the driving current Idrive. In other embodiments, the current source 210 can be any circuit capable of providing the reference current Iref.

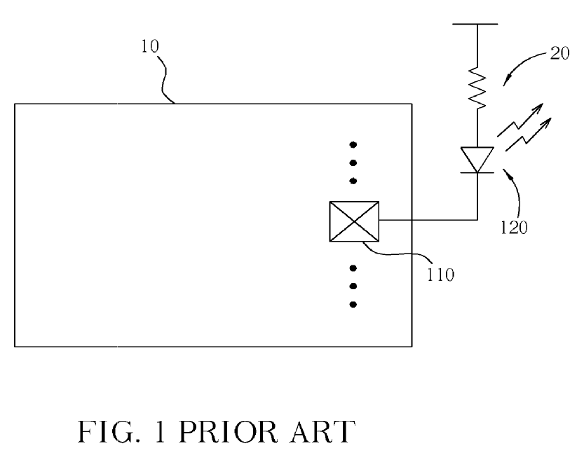

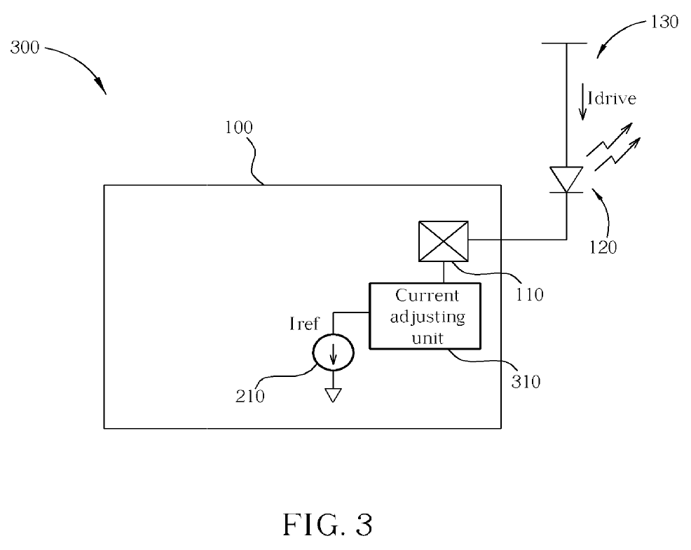

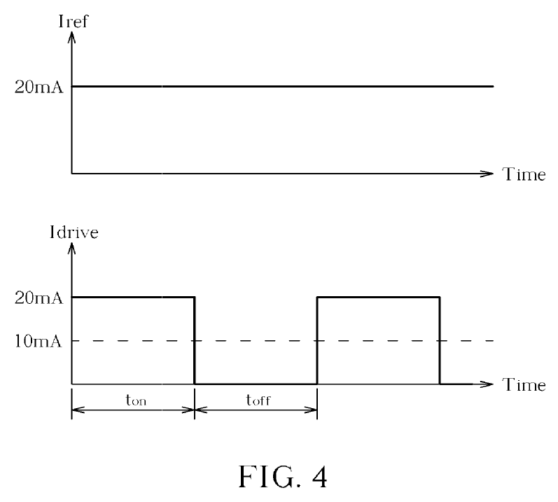

Please note that, in the above embodiment, the current value of the driving current Idrive is equal to that of the reference current Iref; however, this is only for illustrative purposes and is not a limitation of the present invention. Please refer to FIG. 3. FIG. 3 is a diagram illustrating a light emitting diode circuit 300 according to a second exemplary embodiment of the present invention. As connections and functions of the elements of the light emitting diode circuit 300 shown in FIG. 3 are similar to elements with the same name in the light emitting diode circuit 200 in FIG. 1, further descriptions are not detailed here for the sake of brevity. As shown in FIG. 3, the chip 100 of the light emitting diode circuit 300 comprises not only the current source 210 and the pad 110 but also a current adjusting unit 310. The current adjusting unit 310 is coupled between the current source 210 and the pad 110, and serves as a current control unit with the current source 210 for controlling a current conducted state between the current source 210 and the light emitting diode 120 to adjust the driving current Idrive. Then, the light emitting diode 120 generates a light source according to the driving current Idrive. In this embodiment, the current adjusting unit 310 is an electronic or mechanical switch for controlling a current conducted period ton and a current non-conducted period toff between the current source 210 and the light emitting diode 120 to adjust the driving current Idrive in order to control the average current value of the driving current Idrive. In the current conducted period ton, the current value of the driving current Idrive is equal to that of the reference current Iref; in the current non-conducted period toff, the current value of the driving current Idrive is equal to zero. Please refer to FIG. 4. FIG. 4 is a diagram illustrating a relation of the reference current Iref relative to the driving current Idrive. For example, assuming that the current adjusting unit 310 (the constant current source) provides the reference current Iref as 20 mA, the current value of the driving current Idrive is equal to that of the reference current Iref (20 mA) in the current conducted period ton; the current value of the driving current Idrive is equal to zero in the current non-conducted period toff. That is, the current adjusting unit 310 controls the ratio of the current conducted period ton to the current non-conducted period toff to be 1, thus the average current value of the driving current Idrive is equal to 10 mA. Please note that the current value of the reference current Iref and the ratio of the current conducted period ton to the current non-conducted period toff mentioned in the above embodiment are merely for illustrative purposes, and are not limitations of the present invention. In other embodiments, the objective of adjusting the average current can be achieved without opening the switch (i.e., an open circuit). For example, when the current source 210 and the light emitting diode 120 are in a conductive state, the current adjusting unit 310 can control an amount of conducted current for the reference current Iref to adjust the average current for the driving current Idrive.

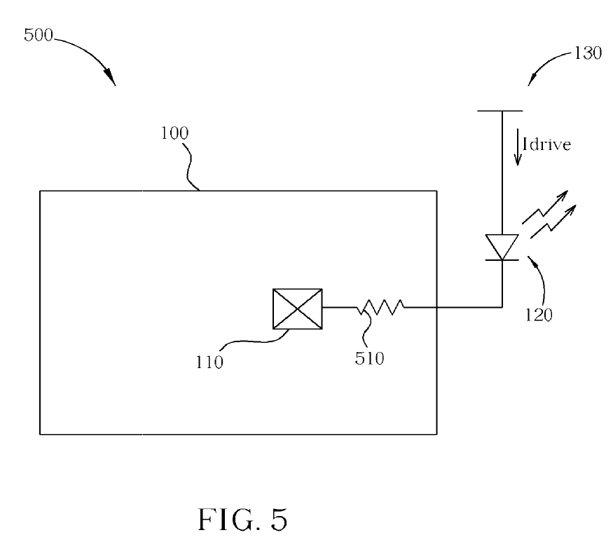

Please refer to FIG. 5. FIG. 5 is a diagram illustrating a light emitting diode circuit 500 according to a third exemplary embodiment of the present invention. As shown in FIG. 5, the light emitting diode circuit 500 comprises a chip 100, a light emitting diode 120 and a predetermined voltage source 130. The light emitting diode 120 and the predetermined voltage source 130 are both positioned outside of the chip 100. The chip 100 further comprises a resistance unit 510 and a pad 110. The light emitting diode 120 is coupled between the predetermined voltage source 130 and the pad 110. The resistance unit 510 is coupled between the pad 110 and the light emitting diode 120, and serves as a current control unit for controlling a driving current Idrive. The light emitting diode 120 generates a light source according to the driving current Idrive. The function of the resistance unit 510 (e.g., a resistor) is the same as the typical current-limiting resistor mentioned in the prior art, but the resistance unit 510 is integrated inside the chip 100. In this way, the circuit structure outside of the chip can be simplified. Please note that, in this embodiment, the resistance unit 510 is a constant resistor; however, this is not a limitation of the present invention. In other words, the resistance unit 510 can be a variable resistor depending on design requirements in other embodiments.

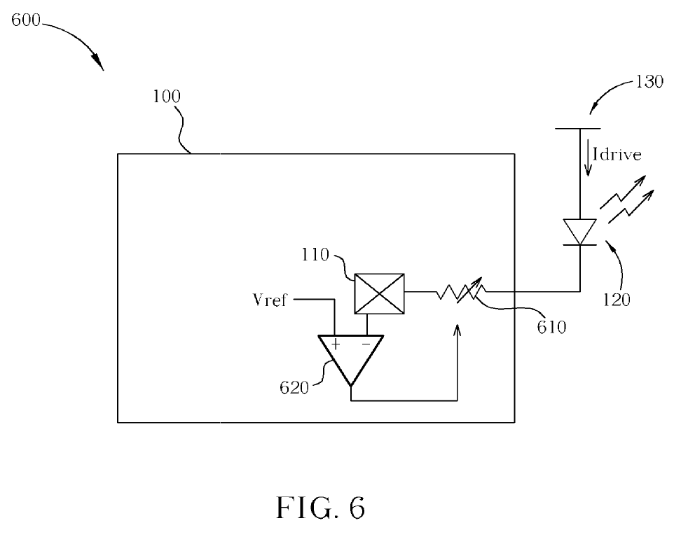

Please refer to FIG. 6. FIG. 6 is a diagram illustrating a light emitting diode circuit 600 according to a fourth exemplary embodiment of the present invention. As shown in FIG. 6, the light emitting diode circuit 600 comprises a chip 100, a light emitting diode 120 and a predetermined voltage source 130. The light emitting diode 120 and the predetermined voltage source 130 are both positioned outside of the chip 100. The chip 100 further comprises a variable resistor 610, an operation amplifier 620 and a pad 110. The light emitting diode 120 is coupled between the predetermined voltage source 130 and the pad 110. The variable resistor 610 is coupled between the pad 110 and the light emitting diode 120. The differential input nodes of the operation amplifier 620 are respectively coupled to a reference voltage Vref and the pad 110, and the output node of the operation amplifier 620 is coupled to the variable resistor 610. The variable resistor 610 and the operation amplifier 620 serve as a current control unit. The operation amplifier 620 adjusts the resistance of the variable resistor 610 according to the reference voltage Vref to control a driving current Idrive. Then, the light emitting diode 120 generates a light source according to the driving current Idrive. In one embodiment the variable resistor 610 can be implemented by a transistor (not shown in FIG. 6). The gate of the transistor is coupled to the output node of the operation amplifier 620, the drain of the transistor is coupled to the light emitting diode 120, and the source of the transistor is coupled to the pad 110. Therefore, the reference voltage Vref can be determined according to the required current value of the driving current Idrive. Even if the problem of the process, temperature or voltage shift occurs, the operation amplifier 620 can still change the resistance of the transistor dynamically with the shift by simply controlling the gate voltage of the transistor. In this way, the current value of the driving current Idrive falls within a predetermined range to prevent the current value from varying too much.

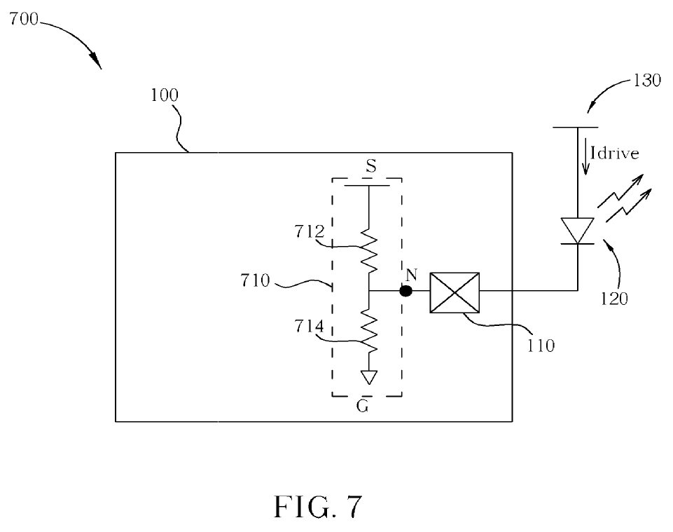

Please refer to FIG. 7. FIG. 7 is a diagram illustrating a light emitting diode circuit 700 according to a fifth exemplary embodiment of the present invention. As shown in FIG. 7, the light emitting diode circuit 700 comprises a chip 100, a light emitting diode 120 and a predetermined voltage source 130. The light emitting diode 120 and the predetermined voltage source 130 are both positioned outside of the chip 100. The chip 100 further comprises a voltage dividing circuit 710 and a pad 110. The light emitting diode 120 is coupled between the predetermined voltage source 130 and the pad 110. A voltage output node Nout of the voltage dividing circuit 710 is coupled to the light emitting diode 120. The voltage dividing circuit 710 serves as a current control unit for setting a voltage level at the voltage output node Nout to control the current value of the driving current Idrive. Then, the light emitting diode 120 generates a light source according to the driving current Idrive. In this embodiment, the voltage dividing circuit 710 comprises a first resistor 712 and a second resistor 714. One end of the first resistor 712 is coupled to a voltage source S, and another end of the first resistor 712 is coupled to the voltage output node Nout. One end of the second resistor 714 is grounded, and another end of the second resistor 714 is also coupled to the voltage output node Nout. Since adjusting the voltage level of the voltage output node Nout by utilizing different combinations of the first resistor 712 and the second resistor 714 should be readily appreciated by those skilled in the art, further description is omitted here for the sake of brevity.

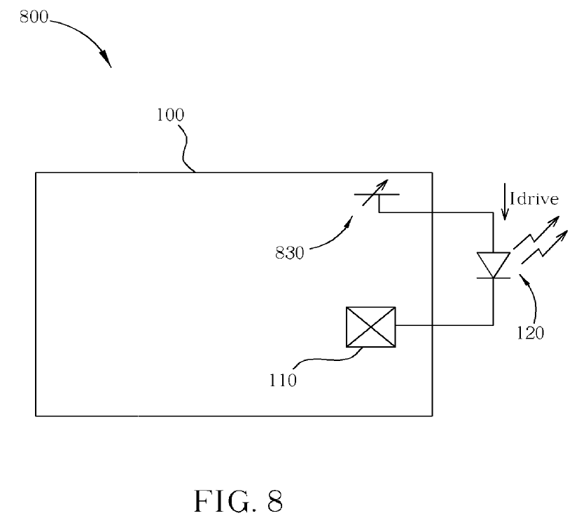

Please refer to FIG. 8. FIG. 8 is a diagram illustrating a light emitting diode circuit 800 according to a sixth exemplary embodiment of the present invention. As shown in FIG. 8, the light emitting diode circuit 800 comprises a chip 100 and a light emitting diode 120 that is positioned outside of the chip 100. The chip 100 comprises a tunable voltage source 830 and a pad 110. The light emitting diode 120 is coupled between the tunable voltage source 830 and the pad 110. The tunable voltage source 830 serves as a current control unit for adjusting an output voltage level thereof to control the current value of a driving current Idrive. Then, the light emitting diode 120 generates a light source according to the driving current Idrive.

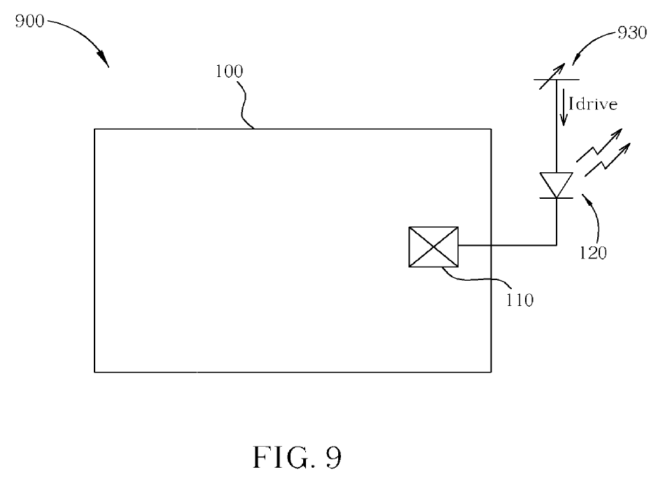

Briefly summarized, in the light emitting diode circuits 200, 300, 400, 500, 600, 700 and 800 of the above embodiments, the chip 100 is utilized for controlling the current value of the driving current Idrive flowing through the light emitting diode 120. In other embodiments, the current value of the driving current Idrive flowing through the light emitting diode 120, however, can be controlled by an element outside of the chip 100 (not the typical current-limiting resistor). Please refer to FIG. 9. FIG. 9 is a diagram illustrating a light emitting diode circuit 900 according to a seventh exemplary embodiment of the present invention. As shown in FIG. 9, the light emitting diode circuit 900 comprises a chip 100, a light emitting diode 120 and a tunable voltage source 930. The light emitting diode 120 and tunable voltage source 930 are both positioned outside of the chip 100. The chip 100 comprises a pad 110. The light emitting diode 120 is coupled between the tunable voltage source 930 and the pad 110. The tunable voltage source 930 serves as a current control unit for adjusting an output voltage level thereof to control the current value of a driving current Idrive. The light emitting diode 120 then generates a light source according to the driving current Idrive.

Compared to the prior art, the light emitting diode circuits disclosed in the prevent invention can control the current value of the driving current flowing through the light emitting diode without an extra current-limiting resistor; thus, the circuit design can be simplified and the production cost can also be reduced.

Those skilled in the art will readily observe that numerous modifications and alterations of the device and method may be made while retaining the teachings of the invention.

What is claimed is:

1. A light emitting diode circuit, comprising:
a chip, comprising:
a current control unit, for controlling a driving current flowing through a path; and
a light emitting diode, positioned outside of the chip and coupled to the path, the light emitting diode generating a light source according to the driving current.

2. The light emitting diode circuit of claim 1, wherein the current control unit comprises:
a current source, coupled to the light emitting diode, for providing the driving current to the path according to a control voltage.

3. The light emitting diode circuit of claim 2, wherein the current control unit further comprises:
a current adjusting unit, coupled between the current source and the light emitting diode, for controlling a current conducted state between the current source and the light emitting diode to adjust the driving current.

4. The light emitting diode circuit of claim 3, wherein the current adjusting unit controls a current conducted period and a current non-conducted period between the current source and the light emitting diode to adjust the driving current.

5. The light emitting diode circuit of claim 3, wherein the current adjusting unit controls an amount of conducted current when the current source and the light emitting diode are in a conductive state for adjusting the driving current.

6. The light emitting diode circuit of claim 1, wherein the current control unit is a resistor.

7. The light emitting diode circuit of claim 1, wherein the current control unit comprises:
a variable resistor, coupled to the light emitting diode; and
an operation amplifier, coupled to the variable resistor, for adjusting a resistance of the variable resistor according to a reference voltage.

8. The light emitting diode circuit of claim 1, wherein the current control unit comprises:
a voltage dividing circuit, having a voltage output node coupled to the light emitting diode, the voltage dividing circuit setting a voltage level at the voltage output node to control the driving current.

9. The light emitting diode circuit of claim 1, wherein the current control unit is a tunable voltage source, and the light emitting diode generates the light source according to the driving current generated from the tunable voltage source.

10. The light emitting diode circuit of claim 1, wherein the light emitting diode is coupled to a tunable voltage source outside of the chip.
